(19) United States
(12) Patent Application Publication
(10) Pub. No.: US 2019/0253158 A1
(43) Pub. Date: Aug. 15, 2019

(54) MEASUREMENT SYSTEM AND METHOD FOR OPERATING A MEASUREMENT SYSTEM

(71) Applicant: Rohde & Schwarz GmbH & Co. KG, Munich (DE)

(72) Inventors: Corbett Rowell, Munich (DE); Benoît Derat, Munich (DE)

(73) Assignee: Rohde & Schwarz GmbH & Co. KG, Munich (DE)

(21) Appl. No.: 15/897,502

(22) Filed: Feb. 15, 2018

(51) Int. Cl. H04B 17/10; G01R 29/08; G01R 29/10

(52) U.S. Cl. CPC H04B 17/10; G01R 29/105; G01R 29/0878

(57) ABSTRACT

A measurement system comprising a device under test, at least two feed antennas, a shielded space, and at least one of a signal generation unit and a signal analysis unit is disclosed. The device under test comprises at least two sub-arrays, each sub-array being configured to generate an electromagnetic beam. The feed antennas are each allocated to a sub-array and are each configured to at least one of generate an electromagnetic beam with defined electromagnetic properties in a certain area assigned to the device under test and receive an electromagnetic beam from the respective sub-array. The feed antennas are connected to the at least one of the signal generation unit and the signal analysis unit, and the device under test and the feed antennas are assigned to the shielded space. Moreover, a method for operating a measurement system is provided.

### FIELD OF THE DISCLOSURE

Embodiments of the present disclosure relate generally to a measurement system as well as a method for operating a measurement system.

### BACKGROUND

With frequencies employed for communication becoming higher and higher, in particular in the field of mobile communication, requirements imposed on the communication devices are also on the rise. For example, certain directional sending and directional receiving properties are required to compensate for the increased path loss at higher frequencies.

Communication devices with multiple antennas mounted on a single base member are commonly used for simultaneous communication with multiple other devices or for increasing the accessible bandwidth.

After fabrication, these devices need to be tested to ensure that they have the exact properties needed for operation. Measurement devices, however, should not be connected to the communication devices via cable, as this would alter the behavior of the communication device. Moreover, a check of quality step after fabrication should take as little time as possible in serial production of the communication devices.

Therefore, there is a need for a measurement system as well as a method for operating a measurement system that is capable of precise and fast testing of the properties of the devices under test.

### SUMMARY

Embodiments of the present disclosure provide a measurement system. The measurement system comprises a device under test, at least two feed antennas, a shielded space, and at least one of a signal generation unit and a signal analysis unit. The device under test comprises at least two sub-arrays, each sub-array being configured to generate an electromagnetic beam. The feed antennas are each allocated to a sub-array and are each configured to at least one of generate an electromagnetic beam with defined electromagnetic properties in a certain area assigned to the device under test and receive an electromagnetic beam from the respective sub-array. The feed antennas are connected to the at least one of the signal generation unit and the signal analysis unit, and the device under test and the feed antennas are assigned to the shielded space.

With the proposed measurement system, two kinds of measurements can be done. In a first type of measurement, electromagnetic beams are actively generated via the sub-arrays of the device under test and measured via the feed antennas. In a second type of measurement, zones with defined electromagnetic properties (sometimes also referred to as “quiet zones”) are generated (via the feed antennas) at the sub-arrays, which induce a response signal from the sub-arrays. This means that the zones with defined electromagnetic properties (“quiet zones”) are generated such that they are assigned to the surface of the respective sub-array, in particular the surface facing the feed antennas. By measuring the response signals via the feed antennas (which are connected to the signal analysis unit), the sub-arrays' properties can be tested. The signal generation unit may be configured to vary the defined electromagnetic properties in the quiet zones, so that the sub-arrays can be tested under various circumstances. Hence, real operation conditions can be tested. Moreover, the device under test can be probed within a shielded space where electromagnetic perturbations from the environment are not present, which allows for a high accuracy of the measurements. In particular, the device under test and the feed antennas are arranged within the shielded space. The shielded space may be a shielded room or a shielded chamber. The proposed measurement system is suitable for fast testing of the device under test as several sub-arrays can be probed simultaneously. Thus, the measurement system can be used in a production line as a final testing step.

According to one aspect of the disclosure, the feed antennas are each configured to generate an electromagnetic beam with defined electromagnetic properties in an area of the respectively allocated sub-array. In particular, the size of each quiet zone essentially matches the size of the corresponding sub-array. This allows for each sub-array being independently tested at the same time, wherein the various measurements do not interfere with one another.

According to another aspect, each feed antenna is allocated to a single sub-array, respectively. Thus, each sub-array can be tested without disturbance from another sub-array. The feed antennas each may generate zones with defined electromagnetic properties being restricted with regard to their areas.

In one embodiment of the present disclosure, the number of feed antennas is equal to the number of sub-arrays. This way, the whole device under test can be probed in only one measurement iteration, thereby reducing the time for probing the device under test. Each feed antenna provides a zone with defined electromagnetic properties that is assigned to the respective sub-array of the device under test.

Each sub-array may be configured to generate an electromagnetic beam using a beamforming algorithm. In particular, the sub-arrays are each configured to generate an electromagnetic beam with defined directional sending properties in order to compensate for a path loss at an employed frequency. The beamforming algorithm may be executed by a processing unit being part of the device under test so that the processing unit controls the electromagnetic beams generated based on the beamforming algorithm.

In a further aspect, the feed antennas are each arranged opposite to the respective allocated sub-array. This way, the main transmission direction of the sub-arrays is probed by the feed antennas.

According to another aspect, the feed antennas are mounted on a wall of the shielded space opposite to the device under test. In some embodiments, the feed antennas may be mounted such that the main sending and receiving direction is adjustable via the signal generation unit by beam forming or rather beam steering. A testing location for the device under test is provided within the shielded space. Thus, the feed antennas are mounted opposite to the testing location.

In another embodiment of the present disclosure, at least two measuring probes are arranged within the shielded space, each measuring probe being connected to the signal analysis unit and being configured to receive electromagnetic waves. The measuring probes may be mounted at a fixed position or may be movable within the shielded space. The measuring probes may be configured to measure at least one of an amplitude, a power distribution and a phase of the electromagnetic beams emitted by the sub-arrays, in particular for probing directional characteristics of the sub-arrays or for beam steering measurements. For instance, the measuring probes are established by measuring antennas.

The measurement system may comprise a conveyor configured to transport the device under test from outside of the shielded space into the shielded space and vice versa. The conveyor may be configured to sequentially transport several devices to the shielded space for successively probing the several devices, which makes the measurement system especially suitable for serial production. A driving unit is provided that drives the conveyor, for example, in a step-wise manner, so that a continuous measurement of several devices under test can be ensured in an efficient manner.

Generally, the conveyor may comprise at least two sub-conveyors establishing the conveying path for the devices under test. One of the sub-conveyors can be located completely within the shielded space.

In another aspect, the shielded space comprises at least one aperture and sealing means for reversibly sealing the at least one aperture. The sealing means are configured to prevent electromagnetic waves from entering the shielded space via the aperture, so that precision measurements within the shielded space are possible. The sealing means may comprise sliding doors, in particular automatic sliding doors, whose direction of movement is perpendicular to the direction of movement of the conveyor (as indicated by the arrows in FIG. 1). In a certain embodiment, the shielded space may comprise two apertures on two opposite sides of the shielded space, wherein sealing means are assigned to each aperture. Hence, a linear movement of the devices under test is ensured.

Embodiments of the present disclosure also provide a method for operating a measurement system. The method comprises the following steps:

inserting a device under test into a shielded space, the device under test comprising at least two sub-arrays; and

measuring electromagnetic beams emitted by the sub-arrays via at least two feed antennas;

the feed antennas each being allocated to a sub-array. Therefore, the properties of several sub-arrays are tested at the same time, thereby reducing the overall time needed for probing the device under test. By probing the device under test within the shielded space, perturbations from the environment are eliminated and the measurements can be performed with high accuracy.

The electromagnetic beams may be actively generated via the sub-arrays. This way, the device under test is in an active sending mode so that the device under test may be tested directly, namely in the active sending mode. Moreover, the device under test may be connected with a power supply. In some embodiments, the measurement system may comprise a power supply that is configured to be connected to the device under test. Alternatively, the device under test may comprise a mobile power supply, such as an accumulator.

In one embodiment of the present disclosure, the sub-arrays are induced to generate the electromagnetic beams by electromagnetic waves emitted by the feed antennas. The response signal is then measured via the feed antennas. Due to (approximate) reciprocity, the sending characteristics of the sub-arrays can be tested in this way without the need of a power supply for the device under test. In other words, the sub-arrays are stimulated to emit electromagnetic beams (response signal) to be measured via the feed antennas. This measurement corresponds to a passive sending mode.

In another embodiment, the electromagnetic waves are generated by the feed antennas such that they have defined electromagnetic properties in certain areas (“quiet zones”) of the device under test. This allows for a reproducible measurement of the sub-arrays' properties. The defined electromagnetic properties in the quiet zones may be varied, so that the sub-arrays are probed under varying circumstances.

Hence, the feed antennas are used for stimulating the sub-arrays and for receiving the electromagnetic beams stimulated previously.

According to another aspect, the electromagnetic waves are generated by the feed antennas such that they have defined electromagnetic properties in the areas of the respective sub-arrays. In particular, each quiet zone is generated such that its size essentially matches the size of the corresponding sub-array. This allows for each sub-array being independently probed at the same time, wherein the various measurements do not interfere with one another.

In a certain embodiment of the present disclosure, the electromagnetic beams emitted by the sub-arrays are additionally measured via at least two measuring probes arranged within the shielded space. In some embodiments, at least one of an amplitude, a power distribution and a phase of the electromagnetic beams emitted by the sub-arrays may be measured, thereby probing directional characteristics of the sub-arrays.

According to an aspect, the feed antennas each are allocated to a single sub-array. Thus, each sub-array has its own feed antenna that may be used for inducing the respective sub-array to generate electromagnetic beams or rather stimulating the respective sub-array appropriately.

Moreover, the measurement system used by the method may correspond to the one defined above.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 shows a schematic view of one representative embodiment of a measurement system according to the disclosure;

FIG. 2 shows a schematic flow chart of one embodiment of a method according to the disclosure; and

FIG. 3 shows a schematic flow chart of another embodiment of a method according to the disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

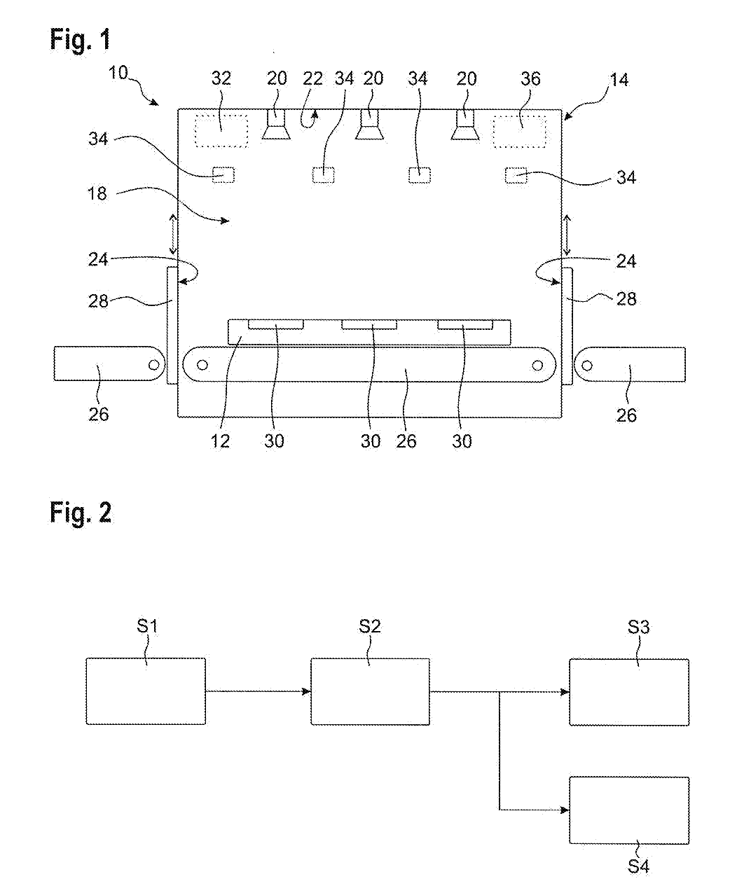

In FIG. 1, a measurement system 10 is shown. The measurement system 10 comprises a device under test 12 and a measurement apparatus 14. The measurement apparatus 14 comprises shielding means 16, which are configured to absorb or reflect electromagnetic waves from the environment of the measurement apparatus 14, such that these electromagnetic waves are blocked off from a shielded space 18 defined by the shielding means 16.

In some embodiments, the shielding means 16 may comprise metallic walls. Alternatively, the shielding means 16 may be formed by an arbitrary suitable material coated with an absorptive layer or with an absorptive paint. In some embodiments, the shielding means 16 are provided by a housing of the measurement apparatus 14 that limits the shielded space 18 appropriately.

Within the shielded space 18, several feed antennas 20 are mounted on a wall 22 of the shielded space 18 such that the feed antennas 20 may at least one of emit electromagnetic waves into the shielded space 18 and receive electromagnetic waves from the shielded space 18. This means that the feed antennas 20 are enabled to emit electromagnetic waves into the shielded space 18 and/or receive electromagnetic waves from the shielded space 18.

The shielding means 16 comprise at least one aperture 24. In the embodiment shown in FIG. 1, the shielding means 16 comprises two apertures 24 being opposite to each other.

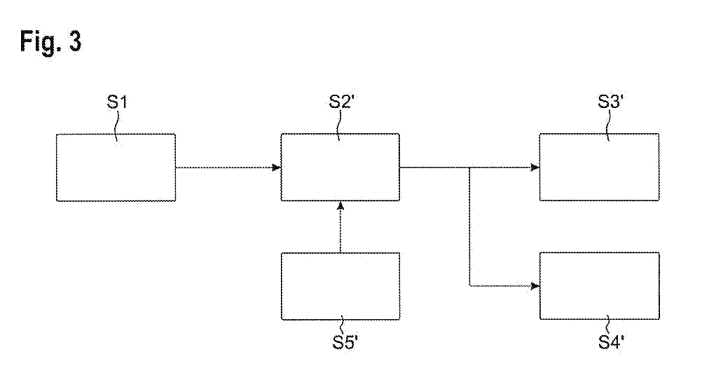

Moreover, the measurement system 10 may comprise a conveyor 26 that is configured to transport the device under test 12 from outside of the shielded space 18 into the shielded space 18 through sealing means 28 and vice versa. Thus, the conveyor 26 establishes a conveying path for the device under test 12 across the shielded space 18 for measuring purposes as will be described later with respect to FIGS. 2 and 3.

As shown in FIG. 1, the conveyor 26 may be established by three sub-conveyors that interact with each other to establish the common conveying path. One of the sub-conveyors is completely located within the shielded space 18.

The sealing means 28 are configured to reversibly shut the apertures 24 such that electromagnetic waves from outside the shielded space 18 are blocked off from the shielded space 18 so that defined conditions can be ensured within the shielded space 18. In the embodiment shown in FIG. 1, the sealing means 28 are formed as sliding doors that may slide in a direction being perpendicular to the conveying direction as indicated by the arrows. Other seals may be practiced with embodiments of the present disclosure.

The device under test 12 comprises several sub-arrays 30 that are each configured to generate an electromagnetic beam. The device under test 12 may be a communication device, wherein the several sub-arrays 30 may be used for simultaneous communication with multiple other devices or for increasing the accessible bandwidth. For this purpose, each sub-array 30 may be configured to generate an electromagnetic beam using a beamforming algorithm. The beamforming algorithm may be executed by a processing unit that controls the electromagnetic beams generated appropriately. The processing unit may include software, hardware, or combinations thereof, for implementing the beamforming algorithm.

Each feed antenna 20 is allocated to a single sub-array 30 and mounted on the wall 22 opposite to the respectively allocated sub-array 30. In the embodiment shown in FIG. 1, the number of feed antennas 20 is equal to the number of sub-arrays 30, such that all sub-arrays 30 can be probed in only one measurement iteration, as it is outlined in the following with reference to FIGS. 2 and 3.

First, the device under test 12 is inserted into the shielded space 18 (step S1), in particular it is transported into the shielded space 18 via the conveyor 26. During step S1, at least one of the sliding doors 28 is open. When the device under test 12 is positioned in the shielded space 18, the sliding doors 28 are shut in order to block off electromagnetic waves from the shielded space 18. Hence, predefined conditions can be ensured within the shielded space 18.

According to one variant of the disclosed method, electromagnetic beams are actively generated via the sub-arrays 30 (step S2). Hence, the device under test 12 is in a sending mode (active mode).

The electromagnetic beams emitted are received via the feed antennas 20 and fed to a signal analysis unit 32, which is connected to the feed antennas 20 in a signal-transmitting manner. The signal analysis unit 32 may be located within or outside of the shielded space 18.

Signals transmitted to the signal analysis unit 32 are now analyzed by the signal analysis unit 32 (step S3). The analyzed signal may be compared to a reference signal stored in the signal analysis unit 32, wherein the reference signal may correspond to a signal of a correctly functioning device under test used as a reference device.

Optionally, the electromagnetic beams emitted by the sub-arrays 30 are additionally measured via at least two measuring probes 34 (step S4) arranged within the shielded space 18. The measuring probes 34 may be connected to the signal analysis unit 32. In step S4, at least one of an amplitude, a power distribution and a phase of the electromagnetic waves emitted by the sub-arrays 30 may be measured. The measuring probes 34 may be mounted immobile or movably within the shielded space 18.

When at least one of analysis and measurement of the electromagnetic waves emitted by the sub-arrays 30 is finished, the device under test 12 is removed from the shielded space 18 via the conveyor 26 and the method described above may be repeated with another device under test 12.

Thus, measurements of several devices under test 12 can be done in a continuous manner.

According to another variant of the disclosed method, electromagnetic beams are generated via the feed antennas 20 (step S2′). In this step, zones with defined electromagnetic properties (sometimes also referred to as “quiet zones”) are generated at the sub-arrays 30. Thereby, a response signal from the sub-arrays 30 is induced. In other words, the sub-arrays 30 are stimulated by the feed antennas 20 to emit the response signal (electromagnetic beams).

The size of the quiet zones may essentially match the size of the sub-arrays 30. In other words, a quiet zone with matching size is assigned to every sub-array 30, so that the various measurements for probing the sub-arrays 30 don't interfere with each other.

The measurement system 10 may comprise a signal generation unit 36 that is configured to vary the defined electromagnetic properties of the quiet zones. Accordingly, the electromagnetic properties may be varied (step S5′) in order to probe the device under test 12 under various circumstances.

Accordingly, different response signals may be stimulated by adapting the electromagnetic properties of the quiet zones.

The response signals are in turn received via the feed antennas 20 (which are connected to the signal analysis unit) and the signals are transmitted to the signal analysis unit 32.

Signals transmitted to the signal analysis unit 32 are then analyzed by the signal analysis unit (step S3′). The analyzed signal may be compared to a reference signal stored in the signal analysis unit 32, wherein the reference signal may correspond to a signal of a correctly functioning device under test as already discussed with regard to FIG. 2.

Optionally, the electromagnetic beams emitted by the sub-arrays 30 are additionally measured via at least two measuring probes 34 (step S4′) arranged within the shielded space 18. The measuring probes 34 may be connected to the signal analysis unit 32. In step S4′, at least one of an amplitude, a power distribution and a phase of the electromagnetic waves emitted by the sub-arrays 30 may be measured.

Thus, a measurement system 10 is provided that can be used to test several devices under test 12 in a fast and efficient manner by over-the-air measurements (OTA measurements). The measurement system 10 may be implemented in a production line, for instance for performing final tests of the devices under test 12 produced.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A measurement system comprising:
a device under test, at least two feed antennas, a shielded space, and at least one of a signal generation unit and a signal analysis unit;
the device under test comprising at least two sub-arrays, each sub-array being configured to generate an electromagnetic beam;
the feed antennas being each allocated to a sub-array, the feed antennas being each configured to at least one of
generate an electromagnetic beam with defined electromagnetic properties in a certain area assigned to the device under test; and
receive an electromagnetic beam from the respective sub-array;
the feed antennas being connected to the at least one of the signal generation unit and the signal analysis unit, and
the device under test and the feed antennas being assigned to the shielded space,
wherein at least two measuring probes are arranged within the shielded space, each measuring probe being connected to the signal analysis unit and being configured to receive electromagnetic waves, wherein the measuring probes are configured to measure at least one from a group consisting of an amplitude, a power distribution and a phase of the electromagnetic beams emitted by the sub-arrays for probing directional characteristics of the sub-arrays or for beam steering measurements.

2. The measurement system according to claim 1, wherein the feed antennas are each configured to generate an electromagnetic beam with defined electromagnetic properties in an area of the respectively allocated sub-array.

3. The measurement system according to claim 1, wherein each feed antenna is allocated to a single sub-array, respectively.

4. The measurement system according to claim 1, wherein the number of feed antennas is equal to the number of sub-arrays.

5. The measurement system according to claim 1, wherein each sub-array is configured to generate an electromagnetic beam using a beamforming algorithm.

6. The measurement system according to claim 1, wherein the feed antennas are each arranged opposite to the respective allocated sub-array.

7. The measurement system according to claim 6, wherein the feed antennas are mounted on a wall of the shielded space opposite to the device under test.

8. (canceled)

9. The measurement system according to claim 1, wherein the measurement system comprises a conveyor configured to transport the device under test from outside of the shielded space into the shielded space and vice versa.

10. The measurement system according to claim 1, wherein the shielded space comprises at least one aperture and a seal configured to reversibly seal the at least one aperture.

11. A method for operating a measurement system, comprising the steps of:
inserting a device under test into a shielded space, the device under test comprising at least two sub-arrays; and
measuring electromagnetic beams emitted by said sub-arrays via at least two feed antennas;
the feed antennas each being allocated to a sub-array,
wherein said electromagnetic beams emitted by said sub-arrays are additionally measured via at least two measuring probes arranged within the shielded space, wherein at least one selected from a group consisting of an amplitude, a power distribution and a phase of the electromagnetic beams emitted by the sub-arrays is measured via the measuring probes for probing directional characteristics of the sub-arrays or for beam steering measurements.

12. The method according to claim 11, wherein said electromagnetic beams are actively generated via the sub-arrays.

13. The method according to claim 11, wherein said sub-arrays are induced to generate said electromagnetic beams by electromagnetic waves emitted by said feed antennas.

14. The method according to claim 13, wherein said electromagnetic waves are generated by the feed antennas such that they have defined electromagnetic properties in certain areas of the device under test.

15. The method according to claim 14, wherein said electromagnetic waves are generated by the feed antennas such that they have defined electromagnetic properties in the areas of the respective sub-arrays.

16. (canceled)

17. The method according to claim 11, wherein the feed antennas each being allocated to a single sub-array.

18. The method according to claim 11, wherein the measurement system comprises said device under test, said at least two feed antennas, said shielded space, and at least one of a signal generation unit and a signal analysis unit;
the device under test comprising at least two sub-arrays, each sub-array being configured to generate an electromagnetic beam;
the feed antennas being each allocated to a sub-array, the feed antennas being each configured to at least one of
generate an electromagnetic beam with defined electromagnetic properties in a certain area assigned to the device under test; and
receive an electromagnetic beam from the respective sub-array;
the feed antennas being connected to the at least one of the signal generation unit and the signal analysis unit, and
the device under test and the feed antennas being assigned to the shielded space.

19. A measurement system comprising:
a device under test, at least two feed antennas, a shielded space, and at least one of a signal generation unit and a signal analysis unit;
the device under test comprising at least two sub-arrays, each sub-array being configured to generate an electromagnetic beam;
the feed antennas being each allocated to a sub-array, the feed antennas being each configured to at least one of
generate an electromagnetic beam with defined electromagnetic properties in a certain area assigned to the device under test; and
receive an electromagnetic beam from the respective sub-array;
the feed antennas being connected to the at least one of the signal generation unit and the signal analysis unit, wherein each feed antenna is allocated to a single sub-array, respectively and the device under test and the feed antennas being assigned to the shielded space.
